(19) United States
(12) Patent Application Publication
(10) Pub. No.: US 2016/0191030 A1
(43) Pub. Date: Jun. 30, 2016

(54) VOLTAGE CONTROLLED DELAY CIRCUIT AND VOLTAGE CONTROLLED OSCILLATOR INCLUDING THE SAME

(71) Applicant: SK hynix Inc., Gyeonggi-do (KR)

(72) Inventor: Kwan-Dong KIM, Gyeonggi-do (KR)

(21) Appl. No.: 14/718,961

(22) Filed: May 21, 2015

(30) Foreign Application Priority Data
Dec. 30, 2014 (KR) 10-2014-0193257

(51) Int. Cl. H03K 5/134; H03K 3/356

(52) U.S. Cl. CPC H03K 5/134; H03K 3/356104; H03K 2005/00026

(57) ABSTRACT

A voltage controlled delay circuit may include a first PMOS transistor suitable for pull-up driving a first differential output node in response to a voltage of the first differential output node, a second PMOS transistor suitable for pull-down driving a second differential output node in response to a voltage of the second differential output node, a third PMOS transistor suitable for pull-up driving the first differential output node in response to a pull-up control voltage, a fourth PMOS transistor suitable for pull-up driving the second differential output node in response to the pull-up control voltage, a first resistor suitable for pull-up driving the first differential output node, a second resistor suitable for pull-up driving the second differential output node, a first NMOS transistor suitable for pull-down driving the first differential output node in response to a voltage of a second differential input node, and a second NMOS transistor suitable for pull-down driving the second differential output node in response to a voltage of a first differential input node.

### CROSS-REFERENCE TO RELATED APPLICATIONS

The present application claims priority of Korean Patent Application No. 10-2014-0193257, filed on Dec. 30, 2014, which is incorporated herein by reference in its entirety.

### BACKGROUND

1. Field

This patent document relates to a voltage controlled delay circuit and a voltage controlled oscillator including the same.

2. Description of the Related Art

Semiconductor devices operate in synchronization with a clock signal, which require the use of an oscillator. A phase locked loop (PLL) is widely used to generate clock signals in many electronic circuits. A voltage controlled oscillator (VCO) is a component of the PLL, which generates a clock signal having a different frequency depending on input voltage. The voltage controlled oscillator includes voltage controlled delay circuits that are coupled in a chain to form a ring oscillator.

Over time, the power supply voltage used in semiconductor devices has decreased while the frequency of their clock signals has increased. The gain of the voltage controlled oscillator (VCO gain) has accordingly increased, Hereafter, the VCO gain is represented by kVCO. When the VCO gain kVCO is large, the voltage controlled oscillator significant changes the frequency of the clock signal with a slight change in the level of a control voltage. The resulting frequency change increases phase noise and jitter which can change the phase of the clock signal.

### SUMMARY

Various embodiments are directed to a technology for lowering voltage controlled oscillator gain and reducing phase noise and jitter that are generated from the voltage controlled oscillator.

In an embodiment, a voltage controlled delay circuit may include a first. PMOS transistor suitable for pull-up driving a first differential output node in response to a voltage of the first differential output node, a second PMOS transistor suitable for pull-down driving a second differential output node in response to a voltage of the second differential output node, a third PMOS transistor suitable for pull-up driving the first differential output node in response to a pull-up control voltage, a fourth PMOS transistor suitable for pull-up driving the second differential output node in response to the pull-up control voltage, a first resistor suitable for pull-up driving the first differential output node, a second resistor suitable for pull-up driving the second differential output node, a first NMOS transistor suitable for pull-down driving the first differential output node in response to a voltage of a second differential input node, and a second NMOS transistor suitable for pull-down driving the second differential output node in response to a voltage of a first differential input node.

The voltage controlled delay circuit may further include a third NMOS transistor suitable for adjusting an amount of current sinking from the first and second NMOS transistors in response to a pull-down control voltage.

Each of the first and second resistors may have a fixed resistance value.

The first and third PMOS transistors and the first resistor may be coupled in parallel between the first differential output node and a power supply voltage terminal, and the second and fourth PMOS transistors and the second resistor may be coupled in parallel between the second differential output node and the power supply voltage terminal. The first NMOS transistor may be coupled between the first differential output node and a common source node, and the second NMOS transistor may be coupled between the second differential output node and the common source node, and the third NMOS transistor may be coupled between the common source node and a ground terminal.

In an embodiment, there is provided a voltage controlled oscillator including first to Nth voltage controlled delay circuits coupled in a chain, where the N is an integer equal to or more than 2. Each of the first to Nth voltage controlled delay circuits may include a first PMOS transistor suitable for pull-up driving a first differential output node in response to a voltage of the first differential output node, a second PMOS transistor suitable for pull-up driving a second differential output node in response to a voltage of the second differential output node, a third PMOS transistor suitable for pull-up driving the first differential output node in response to a pull-up control voltage, a fourth PMOS transistor suitable for pull-up driving the second differential output node in response to the pull-up control voltage, a first resistor suitable for pull-up driving the first differential output node, a second resistor suitable for pull-up driving the second differential output node, a first NMOS transistor suitable for pull-down driving the first differential output node in response to a voltage of a second differential input node, and a second NMOS transistor suitable for pull-down driving the second differential output node in response to a voltage of a first differential input node.

In the first to Nth voltage controlled delay circuits, a second differential output node of a voltage controlled delay circuit at a front stage is coupled to a second differential input node of a voltage controlled delay circuit at a next stage, and a first differential output node of the voltage controlled delay circuit at the front stage is coupled to a first differential input node of the voltage controlled delay circuit at the next stage, and a second differential output node of the Nth voltage controlled delay circuit is coupled to a first differential input node of the first voltage controlled delay circuit, and a first differential output node of the Nth voltage controlled delay circuit is coupled to a second differential input node of the first voltage controlled delay circuit.

Each of the first to Nth voltage controlled delay circuits may include a third NMOS transistor suitable for adjusting an amount of current sinking from the first and second NMOS transistors in response to a pull-down control voltage.

The voltage controlled oscillator may further include a control voltage generation circuit suitable for generating the pull-up control voltage and the pull-down control voltage in response to a control voltage.

The control voltage generation circuit may include a pull-down control voltage generation unit suitable for generating the pull-down control voltage in response to the control voltage, and a pull-up control voltage generation unit suitable for generating the pull-up control voltage in response to the pull-down control voltage. The pull-down control voltage generation unit may include a push-pull amplifier suitable for pull-up driving a first node in response to the control voltage, and pull-down driving the first node in response to the pull-down control voltage, and an operational amplifier suitable for receiving the control voltage and a voltage of the first node, and outputting the pull-down control voltage. The pull-up control voltage generation unit may include a fourth NMOS transistor suitable for pull-down driving an output node of the pull-up control voltage in response to the pull-down control voltage, and one or more fifth PMOS transistors suitable for pull-up driving the output node of the pull-up control voltage in response to the pull-up control voltage.

### BRIEF DESCRIPTION OF THE DRAWINGS

FIG. 1 is a configuration diagram of a voltage controlled oscillator in accordance with an embodiment of the present invention.

FIG. 2 is a configuration diagram of a voltage controlled delay circuit of FIG. 1.

FIG. 3 is a configuration diagram of a control voltage generation circuit of FIG. 1.

FIGS. 4 to 6 are diagrams illustrating frequencies f_{PMOS}, f_{R}, and f based on a change of V_{d}.

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

The drawings are not necessarily to scale and, in some instances, proportions may have been exaggerated in order to clearly illustrate features of the embodiments. When an element is referred to as being connected or coupled to another element, it should be understood that the former can be directly connected or coupled to the latter, or electrically connected or coupled to the latter via an intervening element therebetween. The terms of a singular form may include plural forms unless otherwise stated.

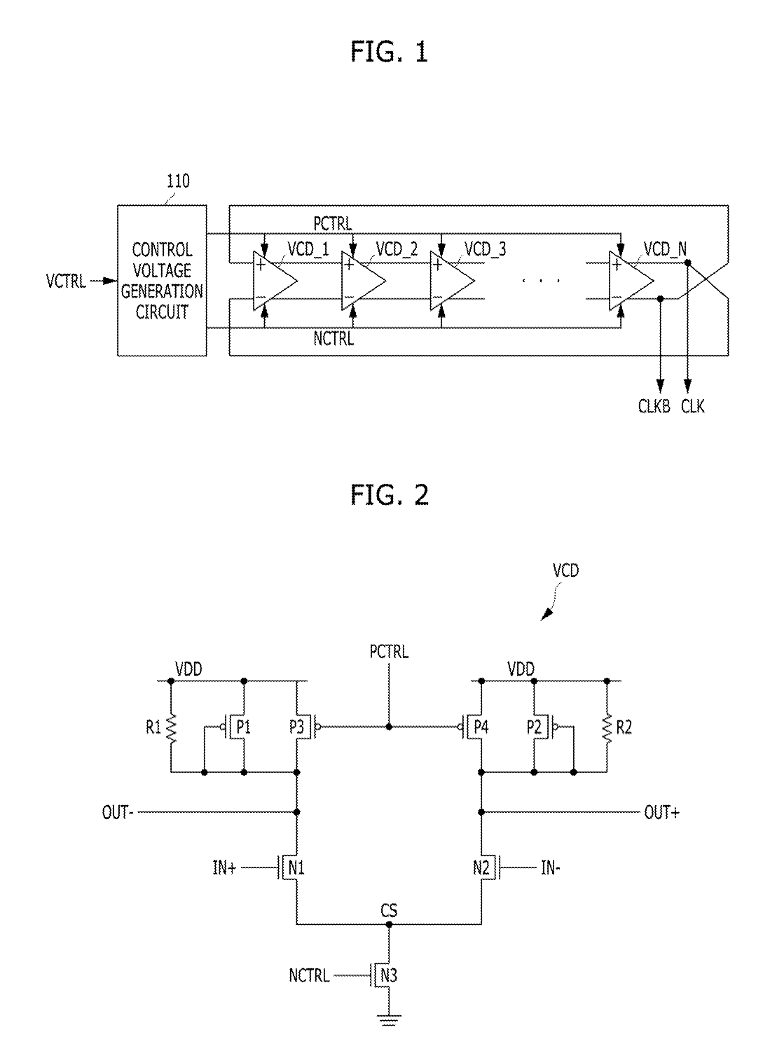

FIG. 1 is a configuration diagram of a voltage controlled oscillator in accordance with an embodiment of the present invention.

Referring to FIG. 1, the voltage controlled oscillator may include first to Nth voltage controlled delay circuits VCD_1 to VCD_N and a control voltage generation circuit 110.

The first to Nth voltage controlled delay circuits VCD_1 to VCD_N may be coupled in the form of a ring oscillator. A positive (+) output of the voltage controlled delay circuit at the front stage (for example, VCD_2) may become a positive (+) input of the voltage controlled delay circuit at the next stage (for example, VCD_3), and a negative (−) output of the voltage controlled delay circuit at the front stage (for example, VCD_2) may become a negative (−) input of the voltage controlled delay circuit at the following stage (for example, VCD_3). Furthermore, a positive (+) output of the voltage controlled delay circuit at the last stage (for example, VCD_N) may become a negative (−) input of the voltage controlled delay circuit at the first stage (for example, VCD_1), and a negative (−) output of the voltage controlled delay circuit at the last stage (for example, VCD_N) may become a positive (+) input of the voltage controlled delay circuit at the first stage (for example, VCD_1). Since a signal is delayed while passing through the first to Nth voltage controlled delay circuits VCD_1 to VCD_N and a signal is delayed and inverted while passing through the Nth voltage controlled delay circuit VCD_N and the first voltage controlled delay circuit VCD_1, clock signals CLK and CLKB may be finally generated.

Each of the first to Nth voltage controlled delay circuits VCD_1 to VCD_N may have a delay value which is changed depending on the levels of a pull-up control voltage PCTRL and a pull-down control voltage NCTRL. When the delay value of the first to Nth voltage controlled delay circuits VCD_1 to VCD_N is changed, the frequency of the clocks CLK and CLKB generated through the voltage controlled oscillator may be changed.

The control voltage generation circuit 110 may generate the pull-up control voltage PCTRL and the pull-down control voltage NCTRL in response to a control voltage VCTRL. The pull-up control voltage PCTRL may adjust the delay value of the first to N-th voltage controlled delay circuits VCD_1 to VCD_N by controlling pull-up driving of the first to N-th voltage controlled delay circuits VCD_1 to VCD_N, and the pull-down control voltage NCTRL may adjust the delay value of the first to N-th voltage controlled delay circuits VCD_1 to VCD_N by controlling pull-down driving of the first to N-th voltage controlled delay circuits VCD_1 to VCD_N.

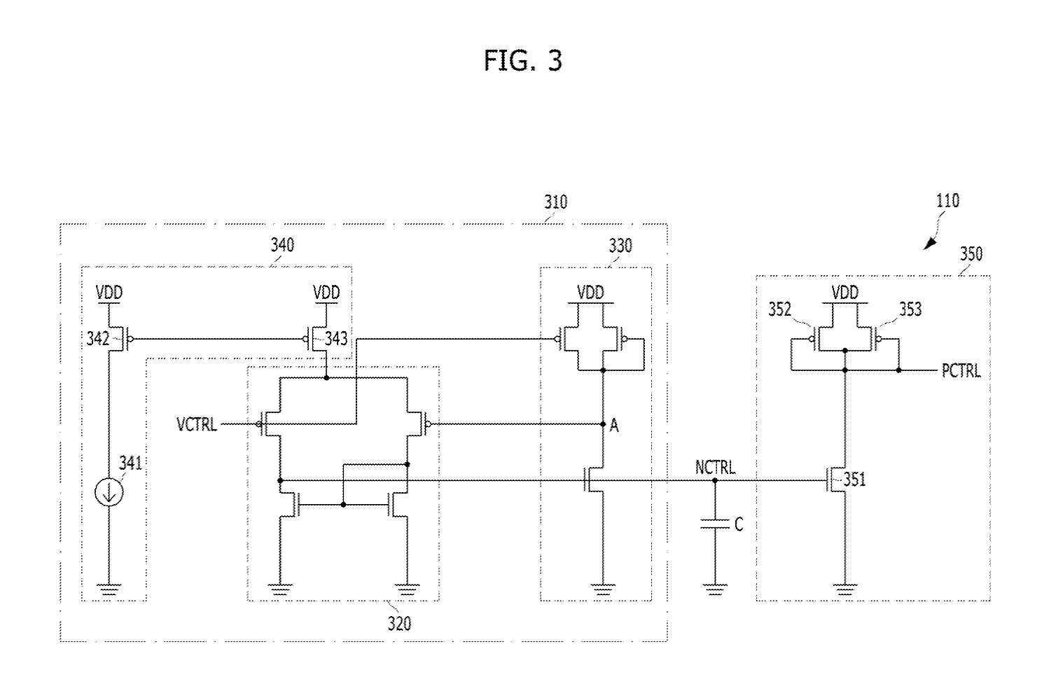

FIG. 2 is a configuration diagram of the voltage controlled delay circuit VCD of FIG. 1. FIG. 2 illustrates one voltage controlled delay circuit VCD, but the voltage controlled delay circuits VCD_1 to VCD_N of FIG. 1 may be configured in the same manner as illustrated in FIG. 2.

Referring to FIG. 2, the voltage controlled delay circuit VCD may include first to fourth PMOS transistors P1 to P4, first and second resistors R1 and R2, and first to third NMOS transistors N1 to N3 The first PMOS transistor P1 may pull-up drive a negative output node OUT− in response to the voltage of the negative output node OUT−. The second PMOS transistor P2 may pull-up drive a positive output node OUT+ in response to the voltage of the positive output node OUT+. The third PMOS transistor P3 may pull-up drive the negative output node OUT− in response to the pull-up control voltage PCTRL, and the fourth PMOS transistor P4 may pull-up drive the positive output node OUT+ in response to the pull-up control voltage PCTRL. The first resistor R1 may pull-up drive the negative output node OUT−, and the second resistor R2 may pull-up drive the positive output node OUT+. The first NMOS transistor N1 may pull-down drive the negative output node OUT− in response to the voltage of a positive input node IN+. The second NMOS transistor N2 may pull-down drive the positive output node OUT+ in response to the voltage of a negative input node IN−. The third NMOS transistor N3 may adjust the amount of current sinking from the first and second NMOS transistors N1 and N2 in response to the pull-down control voltage NCTRL.

The first PMOS transistor P1, the third PMOS transistor P3, and the first resistor R1 may be coupled in parallel between the negative output node OUT− and a power supply voltage terminal VDD. The second PMOS transistor P2, the fourth PMOS transistor P4, and the second resistor R2 may be coupled in parallel between the positive output node OUT+ and the power supply voltage terminal VDD. The first NMOS transistor Ni may be coupled between the negative output node OUT− and a common source node CS, and the second NMOS transistor N2 may be coupled between the positive output node OUT+ and the common source node CS. The third NMOS transistor N3 may be coupled between the common source node CS and a ground terminal and adjust the amount of current sinking to the ground terminal from the common source node CS.

The first and second resistors R1 and R2 are components for lowering the gain kVCO of the voltage controlled oscillator and reducing phase noise and jitter. The first and second resistors R1 and R2 may be passive elements having the same resistance value at all times.

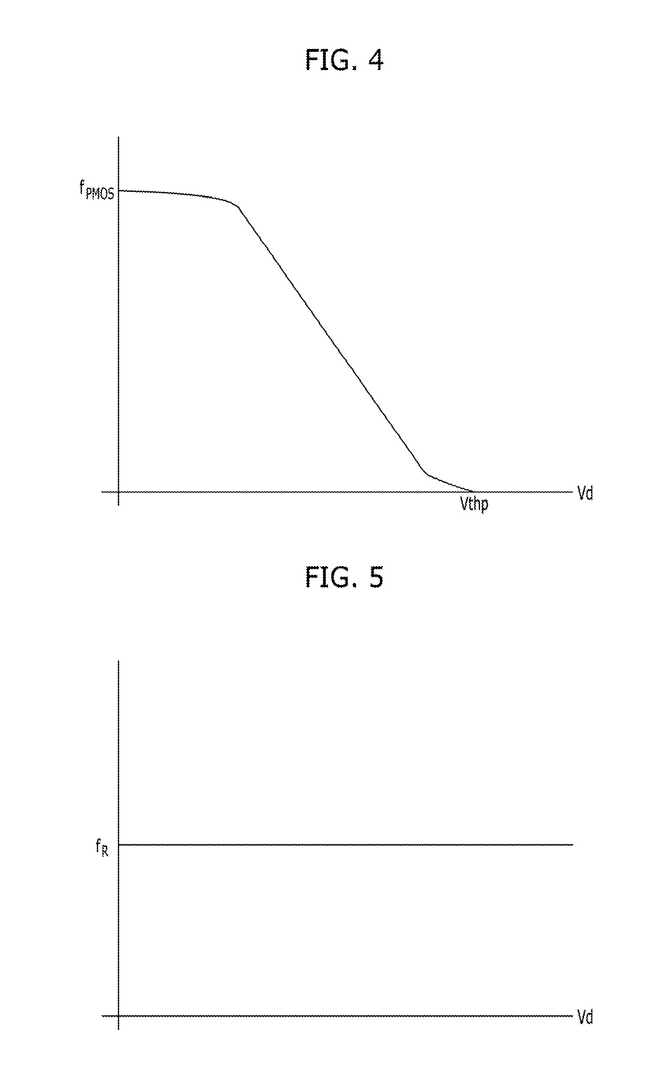

FIG. 3 is a configuration diagram of the control voltage generation circuit 110 of FIG. 1.

Referring to FIG. 3, the control voltage generation circuit 110 may include a pull-down control voltage generation unit 310 and a pull-up control voltage generation unit 350. The pull-down control voltage generation unit 310 may generate the pull-down control voltage NCTRL in response to the control voltage VCTRL, and the pull-up control voltage generation unit 350 may generate the pull-up control voltage PCTRL in response to the pull-down control voltage NCTRL.

The pull-down control voltage generation unit 310 may include an operational amplifier 320, a push-pull amplifier 330, and a current supply unit 340. The current supply unit 340 may include a current source 341 and PMOS transistors 342 and 343. The current source 341 may control the constant amount of current to flow through the PMOS transistors 342 and 343 such that the same amount of current flows through the PMOS transistors 342 and 343. Thus, the current supply unit 340 may supply the constant amount of current to the operational amplifier 320. The operational amplifier 320 may receive the control voltage VCTRL and the voltage of a first node A, and output the pull-down control voltage NCTRL. The push-pull amplifier 330 may pull-up drive the first node A in response to the control voltage VCTRL, and pull-down drive the first node A in response to the pull-down control voltage NCTRL. The pull-down control voltage generation unit 310 may generate the pull-down control voltage NCTRL at a higher level as the level of the control voltage VCTRL is lower, and generate the pull-down control voltage NCTRL at a lower level as the level of the control voltage VCTRL is higher.

The pull-up control voltage generation unit 350 may include an NMOS transistor 351 and PMOS transistors 352 and 351 The NMOS transistor 351 may pull-down drive a node of the pull-up control voltage PCTRL in response to the pull-down control voltage NCTRL, and the PMOS transistors 352 and 353 may pull-up drive the node of the pull-up control voltage PCTRL in response to the pull-up control to voltage PCTRL. FIG. 3 illustrates the two PMOS transistors 352 and 353, but the number of PMOS transistors may be set to an arbitrary integer equal to or more than one, The pull-up control voltage generation unit 350 may generate the pull-up control voltage PCTRL at a lower level as the level of the pull-down control voltage NCTRL is higher, and generate the pull-up control voltage PCTRL at a higher level as the level of the pull-down control voltage NCTRL is lower.

A capacitor C may be used to stably maintain the level of the pull-down control voltage NCTRL. The level of the pull-up control voltage PCTRL as well as the level of the pull-down control voltage NCTRL may be stably maintained by the capacitor C.

FIG. 3 illustrates that the control voltage generation circuit 110 generates the low-level pull-down control voltage NCTRL and the high-level pull-up control voltage PCTRL as the level of the control voltage VCTRL is high, and generates the high-level pull-down control voltage NCTRL and the low-level pull-up control voltage PCTRL as the level of the control voltage VCTRL is low, However, the control voltage generation circuit 110 may be designed to generate the high-level pull-down control voltage NCTRL and the low-level pull-up control voltage PCTRL as the level of the control voltage VCTRL is high, and to generate the low-level pull-down control voltage NCTRL and the high-level pull-up control voltage PCTRL as the level of the control voltage VCTRL is low.

Referring back to FIGS. 1 and 2, a process of lowering the gain kVCO of the voltage controlled oscillator and reducing phase noise and jitter through the resistors R1 and R2 will be described as follows.

The output clock of the voltage controlled oscillator including the N voltage controlled delay circuits VCD_1 to VCD_N may have a frequency of 1/(number of stages*delay value of each stage*2). When the resistors R1 and R2 are omitted from the voltage controlled delay circuits VCD_1 to VCD_N, the frequency of the output clocks CLK and CLKB may be represented by f_{PMOS}, and may be expressed as Equation 1 below.

f_{PMOS}=1/(2×N×Td) [Equation 1]

In Equation 1, Td represents the delay value of each of the voltage controlled delay circuits VCD_1 to VCD_N, and may be expressed as Equation 2 below.

Td=R_{eff}C_{eff} [Equation 2]

In Equation 2, C_{eff} represents an effective capacitance value which is a fixed value obtained by adding a junction capacitance and a line capacitance, and R_{eff} represents an effective resistance value which is a variable value. Depending on how R_{eff} is changed, f_{PMOS} may be determined.

When the resistors R1 and R2 are omitted, two PMOS transistors P1 and P3 or P2 and P4 coupled in parallel to each other in the voltage controlled delay circuits VCD_1 to VCD_N may operate as to a diode when the gate voltage thereof is lower than the threshold voltage Vₜₕₚ of the PMOS transistors. In this case, a current may flow into the PMOS transistors P1 and P3 or P2 and P4 depending on the polarity of an input signal IN+ or IN−. The current I_{d} flowing through the diode may be expressed as Equation 3 below.

I_{d}=β(V_{SD}−Vₜₕₚ)2 [Equation 3]

In Equation 3, β represents one symbol including various coefficients, and V_{SD} represents a source-drain voltage between the PMOS transistors P1 and P3 or P2 and P4.

By checking how the current of the PMOS transistors P1 and P3 or P2 and P4 operating as a diode are changed depending on the drain voltages of the PMOS transistors P1 and P3 or P2 and P4, the effective resistance value R_{eff} may be obtained, First, a value obtained by partially differentiating I_{d} with respect to V_{d} may be expressed as Equation 4 below.

∂I_{d}/∂V_{d}=2β(V_{SD}−Vₜₕₚ) [Equation 4]

Since R=WI, R_{eff}=∂I_{d}/∂V_{d}, and the effective resistance value R_{eff} may be expressed as Equation 5 below.

R_{eff}=∂V_{d}∂I_{d}=1/[2β(V_{SD}−Vₜₕₚ)] [Equation 5]

When Equations 2 and 5 are substituted for Equation 1, f_{PMOS} may be expressed as Equation 6 below.

f_{PMOS}=1/(2×N×R_{eff}×C_{eff})=β(V_{SD}−Vₜₕₚ)/(N×C_{eff}) [Equation 6]

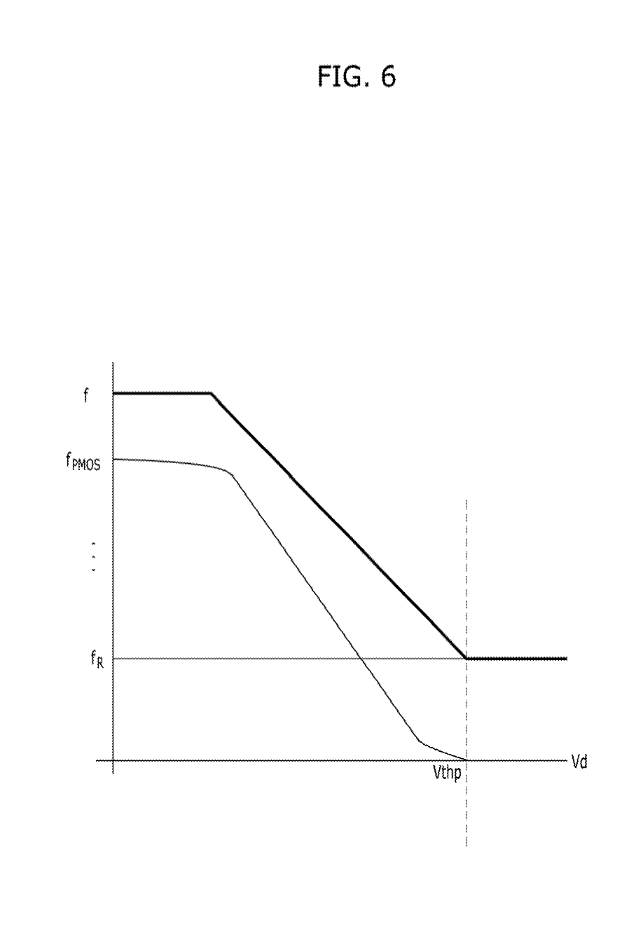

In Equation 6, only V_{SD} is a variable value, and the other values are fixed values. Furthermore, since the source voltage Vs of the PMOS transistors P1 and P3 or P2 and P4 are fixed (i.e., power supply voltage VDD), only the drain voltage V_{d} is a variable which is varied depending on the control voltages PCTRL and NCTRL. FIG. 4 illustrates the frequency f_{PMOS} based on the change of the drain voltage V_{d}. Referring to FIG. 4, the frequency f_{PMOS} linearly increases as the drain voltage V_{d} decreases, Then, when the frequency fPMOS reaches a saturation region, the frequency fPMOS does not linearly increase any more.

When the PMOS transistors P1 to P4 are omitted from the voltage controlled delay circuits VCD_1 to VCD_N, the frequency may be represented by f_{R}, and may be expressed as Equation 7 below.

f_{R}=1/(2×N×R×C_{eff}) [Equation 7]

In Equation 7, R represents the resistance values of the resistors R1 and R2. In this case, since the resistance values R are not changed, the frequency f_{R} is constant regardless of the drain voltage V_{d}. FIG. 5 illustrates the frequency f_{R}.

When each of the voltage controlled delay circuits VCD_1 to VCD_N includes the PMOS transistors P1 to P4 and the resistors R1 and R2, that is, when the voltage controlled delay circuits VCD_1 to VCD_N are configured in the same manner as illustrated in FIG. 2, the frequency f of the output clocks CLK and CLKB of the voltage controlled oscillator may be represented as f=f_{PMOS}+f_{R}. Furthermore, when each of the voltage controlled delay circuits VCD_1 to VCD_N includes the PMOS transistors P1 to P4 and the resistors R1 and R2, the effective capacitance value C_{eff} slightly increases. Thus, an actual frequency f may be set to a downward slope less steep than the frequency f_{PMOS}. FIG. 6 illustrates the frequency f. When the frequencies f and f_{PMOS} are compared to each other with reference to FIG. 6, it is noted that a clock with a high frequency may be easily generated and phase noise and jitter may be reduced through a smaller VCO gain kVCO.

In accordance with the embodiments of the present invention, it is possible to lower the gain of the voltage controlled oscillator, and to reduce phase noise and jitter which are generated from the voltage controlled oscillator.

Although various embodiments have been described for illustrative purposes, it will be apparent to those skilled in the art that various changes and modifications may be made without departing from the spirit and scope of the invention as defined in the following claims.

What is claimed is:

1. A voltage controlled delay circuit, comprising:
a first PMOS transistor suitable for pull-up driving a first differential output node in response to a voltage of the first differential output node;
a second PMOS transistor suitable for pull-down driving a second differential output node in response to a voltage of the second differential output node;
a third PMOS transistor suitable for pull-up driving the first differential output node in response to a pull-up control voltage;
a fourth PMOS transistor suitable for pull-up driving the second differential output node in response to the pull-up control voltage;
a first resistor suitable for pull-up driving the first differential output node;
a second resistor suitable for pull-up driving the second differential output node;
a first NMOS transistor suitable for pull-down driving the first differential output node in response to a voltage of a second differential input node; and
a second NMOS transistor suitable for pull-down driving the second differential output node in response to a voltage of a first differential input node.

2. The voltage controlled delay circuit of claim 1, further comprising:
a third NMOS transistor suitable for adjusting an amount of current sinking from the first and second NMOS transistors in response to a pull-down control voltage.

3. The voltage controlled delay circuit of claim 1, wherein each of the first and second resistors has a fixed resistance value.

4. The voltage controlled delay circuit of claim 1, wherein:
the first and third PMOS transistors and the first resistor are coupled in parallel between the first differential output node and a power supply voltage terminal; and
the second and fourth PMOS transistors and the second resistor are coupled in parallel between the second differential output node and the power supply voltage terminal.

5. The voltage controlled delay circuit of claim 2, wherein:
the first NMOS transistor is coupled between the first differential output node and a common source node;
the second NMOS transistor is coupled between the second differential output node and the common source node; and
the third NMOS transistor is coupled between the common source node and a ground terminal.

6. The voltage controlled delay circuit of claim 1, wherein the first and second differential output nodes are negative and positive output nodes, respectively, and the first and second differential input nodes are negative and positive input nodes, respectively.

7. A voltage controlled oscillator, comprising:
first to Nth voltage controlled delay circuits coupled in a chain, where the N is an integer equal to or more than 2,
wherein each of the first to Nth voltage controlled delay circuits comprises:
a first PMOS transistor suitable for pull-up driving a first differential output node in response to a voltage of the first differential output node;
a second PMOS transistor suitable for pull-up driving a second differential output, node in response to a voltage of the second differential output node;
a third PMOS transistor suitable for pull-up driving the first differential output node in response to a pull-up control voltage;
a fourth PMOS transistor suitable for pull-up driving the second differential output node in response to the pull-up control voltage;
a first resistor suitable for pull-up driving the first differential output node;
a second resistor suitable for pull-up driving the second differential output node;
a first NMOS transistor suitable for pull-down driving the first differential output node in response to a voltage of a second differential input node; and
a second NMOS transistor suitable for pull-down driving the second differential output node in response to a voltage of a first differential input node.

8. The voltage controlled oscillator of claim 7, wherein in the first to Nth voltage controlled delay circuits:
a second differential output node of a voltage controlled delay circuit at a front stage is coupled to a second differential input node of a voltage controlled delay circuit at a next stage;
a first differential output node of the voltage controlled delay circuit at the front stage is coupled to a first differential input node of the voltage controlled delay circuit at the next stage;
a second differential output node of the Nth voltage controlled delay circuit is coupled to a first differential input node of the first voltage controlled delay circuit; and
a first differential output node of the Nth voltage controlled delay circuit is coupled to a second differential input node of the first voltage controlled delay circuit.

9. The voltage controlled oscillator of claim 7, wherein each of the first to Nth voltage controlled delay circuits comprises:
a third NMOS transistor suitable for adjusting an amount of current sinking from the first and second NMOS transistors in response to a pull-down control voltage.

10. The voltage con oiled oscillator of claim 9, further comprising:
a control voltage generation circuit suitable for generating the pull-up control voltage and the pull-down control voltage in response to a control voltage.

11. The voltage controlled oscillator of claim 10, wherein the control voltage generation circuit comprises:
a pull-down control voltage generation unit suitable for generating the pull-down control voltage in response to the control voltage; and
a pull-up control voltage generation unit suitable for generating the pull-up control voltage in response to the pull-down control voltage.

12. The voltage controlled oscillator of claim 11, wherein the pull-down control voltage generation unit comprises:
a push-pull amplifier suitable for pull-up driving a first node in response to the control voltage, and pull-down driving the first node in response to the pull-down control voltage; and
an operational amplifier suitable for receiving the control voltage and a voltage of the first node, and outputting the pull-down control voltage.

13. The voltage controlled oscillator of claim 11, wherein the pull-up control voltage generation unit comprises:
a fourth NMOS transistor suitable for pull-down driving an output node of the pull-up control voltage in response to the pull-down control voltage; and
one or more fifth PMOS transistors suitable for pull-up driving the output node of the pull-up control voltage in response to the pull-up control voltage.

14. The voltage controlled oscillator of claim 7, wherein:
the first and third PMOS transistors and the first resistor are coupled in parallel between the first differential output node and a power supply voltage terminal; and
the second and fourth PMOS transistors and the second resistor are coupled in parallel between the second differential output node and the power supply voltage terminal.

15. The voltage controlled oscillator of claim 9, wherein:
the first NMOS transistor is coupled between the first differential output node and a common source node;
the second NMOS transistor is coupled between the second differential output node and the common source node; and
the third NMOS transistor is coupled between the common source node and a ground terminal.

16. The voltage controlled oscillator of claim 7, wherein each of the first and second resistors has a fixed resistance value.

17. The voltage controlled delay circuit of claim 7, wherein the first and second differential output nodes are negative and positive output nodes, respectively, and the first and second differential input nodes are negative and positive input nodes, respectively.
